(19) United States
(12) Patent Application Publication
(10) Pub. No.: US 2014/0319549 A1
(43) Pub. Date: Oct. 30, 2014

(54) LIGHT EMITTING DIODE PACKAGE HAVING A TRANSPARENT METAL LAYER FUNCTION AS AN ELECTRODE THEREOF

(71) Applicant: ADVANCED OPTOELECTRONIC TECHNOLOGY, INC., Hsinchu Hsien (TW)

(72) Inventors: MING-TA TSAI, Hukou (TW); CHUNG-MIN CHANG, Hukou (TW)

(73) Assignee: ADVANCED OPTOELECTRONIC TECHNOLOGY, INC., Hsinchu Hsien (TW)

(21) Appl. No.: 14/155,263

(22) Filed: Jan. 14, 2014

(30) Foreign Application Priority Data
Apr. 29, 2013 (CN) 2013101550678

(51) Int. Cl. H01L 33/48; H01L 25/075

(52) U.S. Cl. CPC H01L 33/483; H01L 25/0753
USPC 257/88; 257/98

(57) ABSTRACT

A light emitting diode package includes a substrate, a reflective cup formed on the substrate, at least one light emitting diode chip formed on the substrate and surrounded by the reflective cup, a first electrode and a second electrode electrically connected with a bottom electrode and a top electrode of the light emitting diode chip, respectively. The first electrode is an electrically conductive layer, and the second electrode is a transparent and electrically conductive layer. The first electrode directly touches and electrically connects the bottom electrode of the light emitting diode chip, and the second electrode directly touches and electrically connects the top electrode of the light emitting diode chip. The first and second electrodes each have a portion extending to a bottom of the substrate.

### BACKGROUND

1. Technical Field

The disclosure relates to light emitting devices, and more particularly to a light emitting diode package which has a plurality of light emitting diode chips and a transparent meter layer functioning as one of two common electrodes for the light emitting diode chips.

2. Discussion of Related Art

LEDs (light emitting diodes) have many advantages, such as high luminosity, low operational voltage, low power consumption, compatibility with integrated circuits, easy driving, long term reliability, and environmental friendliness. Such advantages have promoted the wide use of the LEDs as a light source.

A typical light emitting diode package includes a plurality of light emitting diode chips, electrodes, a substrate, an encapsulation and a reflective cup. The light emitting diode chips and the electrodes are electrically connected by metal wires. Generally, a space is needed for arranging the wires, which increases a volume of the reflective cup and accordingly a volume of the light emitting diode package. However, this is contrary to a tendency of a thin light emitting diode package. Furthermore, moisture can easily creep into light emitting diode package through a connection between the reflective cup and the encapsulation to damage the light emitting diode chips.

What is needed, therefore, is a light emitting diode package which can overcome the limitations described above.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present light emitting diode package. Moreover, in the drawings, like reference numerals designate corresponding parts throughout the several views.

FIG. 1 is a cross-sectional view of a light emitting diode package in accordance with a first exemplary embodiment of the present disclosure.

FIG. 2 is a top view of the light emitting diode package of FIG. 1.

FIG. 3 is a cross-sectional view of a light emitting diode package in accordance with a second exemplary embodiment of the present disclosure.

### DETAILED DESCRIPTION OF EMBODIMENTS

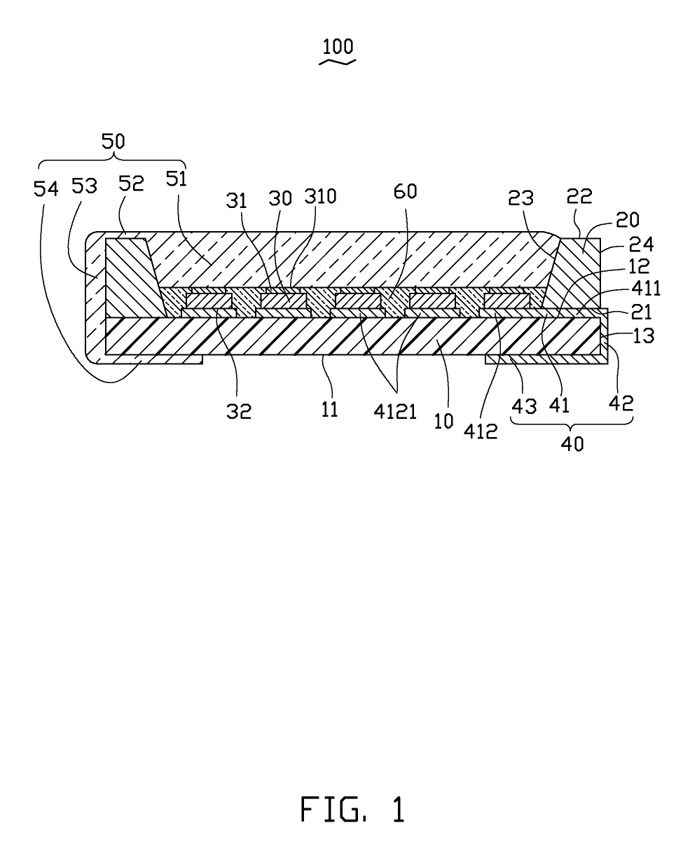

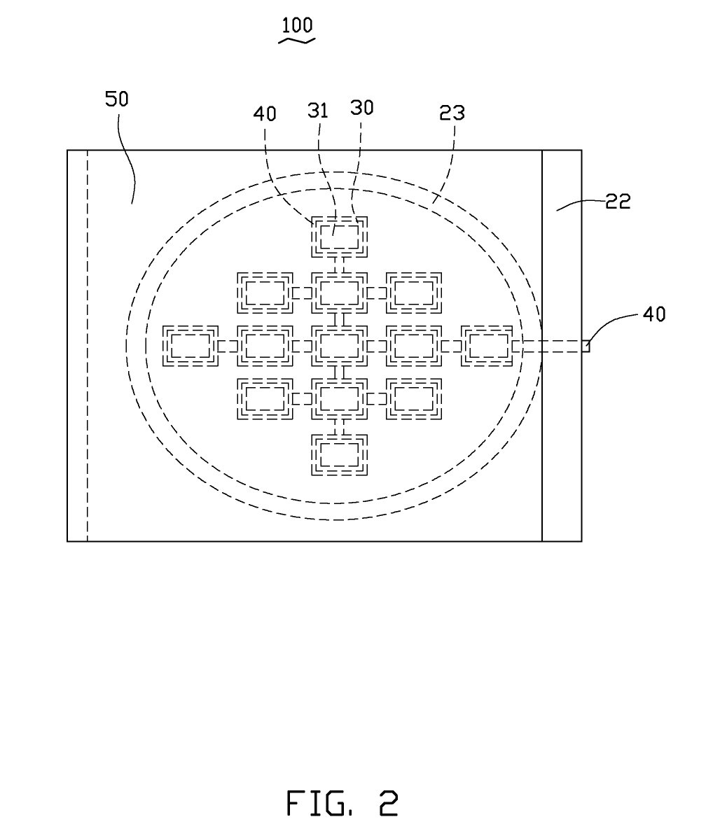

Referring to FIGS. 1 and 2, a light emitting diode package 100 in accordance with a first exemplary embodiment is shown. The light emitting diode package 100 includes a substrate 10, a reflective cup 20 formed on the substrate 10, a plurality of light emitting diode chips 30 formed on the substrate 10 and surrounded by in the reflective cup 20, and a first electrode 40 and a second electrode 50 electrically connected with the light emitting diodes 30.

The substrate 10 is made of EMC (Electrical Magnetic Compatibility), PPA (Polyphthalamide), SMC (Sheet Molding Compound) or other similar materials. The substrate 10 includes a first surface 11, a second surface 12 opposite to the first surface 11 and a third surface 13 connected between the first surface 11 and the second surface 12. The first surface 11 is a bottom surface, the second surface 12 is a top surface and the third surface 13 is a side surface of the substrate 10.

The first electrode 40 is formed on the substrate 10. The first electrode 40 is an electrode layer. The first electrode 40 is made of metal or other electrically conductive materials. The first electrode 40 includes a first portion 41 formed on the second surface 12, a second portion 42 extending from the first portion 41 and attached to the third surface 13 and a third portion 43 extending from the second portion 42 and attached to and beneath the first surface 11, in other words, the second portion 42 is connected between the first portion 41 and the third portion 43. In detail, a first section 411 of the first portion 41 of the first electrode 40 is sandwiched between the reflective cup 20 and the second surface 12 of the substrate 10. A second section 412 of the first portion 41 is received in the reflective cup 20. In the depicted embodiment, the second section 412 includes a plurality of areas 4121 electrically connected with each other. Correspondingly, the plurality of light emitting diode chips 30 which is received in the reflective cup 20 each is formed on a corresponding area 4121 of the second section 412 of the first portion 41 of the first electrode 40, and electrically connected with the first electrode 40.

The light emitting diode chips 30 each include an N-type electrode 32 and a P-type electrode 31 respectively formed on bottom and top ends of the light emitting chip 30. And, the P-type electrode 31 and the N-type electrode 32 are respectively a positive electrode and a negative electrode. In this embodiment, the N-type electrode 32 is a bottom electrode, and the P-type electrode 31 is a top electrode. In detail, a bottom surface of the light emitting diode chip 30 has the N-type electrode 32, and contacts an upper surface of the area 4121 of the first portion 41 of the first electrode 40. The P-type electrode 31 of the light emitting diode chip 30 is formed on a top surface (in FIG. 1) of the light emitting diode chip 30. The P-type electrode 31 has a connecting surface 310, which is far away from the substrate 10. The light emitting diode chips 30 are parallel electrically connected with each other, and the light emitting diode chips 30 have a same thickness and a same electrical structure. In this embodiment (in FIG. 2), the light emitting diode package 100 includes thirteen light emitting diode chips 30. The thirteen light emitting diode chips 30 are arranged in the reflective cup 20 in five rows. The first row has one light emitting diode chip 30, the second row has three light emitting diode chips 30, the third row has five light emitting diode chips 30, the fourth row has three light emitting diode chips 30, and the fifth row has one light emitting diode chip 30.

The reflective cup 20 includes a first connecting surface 21 connected to the first surface 12 of the substrate 10, a second connecting surface 22 opposite to the first connecting surface 21, a third connecting surface 23 defining an inside of the reflective cup 20 and a fourth connecting surface 24 defining an outside of the reflective cup 20. The third connecting surface 23 is connected between the first connecting surface 21 and the second connecting surface 22 at an inner periphery of the reflective cup 20. The fourth connecting surface 24 is connected between the first connecting surface 21 and the second connecting surface 22 at an outer periphery of the reflective cup 20. The third connecting surface 23 is around the light emitting diode chips 30 and has a high reflectivity. The height of the reflective cup 20, which is a distance between the first and second connecting surfaces 22, 23, is more than the thickness of the light emitting diode chips 30.

The second electrode 50 is electrically connected to the P-type electrodes 31 of the light emitting diode chips 30. The second electrode 50 is made of indium tin oxide (ITO) in the depicted embodiment. The ITO is a transparent alloy which allows light to transmit therethrough. The second electrode 50 may be a transparent and electrically conductive layer made of other suitable materials in other embodiments. The second electrode 50 includes a first part 51 received in the reflective cup 20, and covering and electrically contacting the electrically connecting surfaces 310 of the P-type electrodes 31 of the light emitting diode chips 30, a second part 52 extending from the first part 51 and covering the second connecting surface 22 of the reflective cup 20, a third part 53 extending from the second part 52 and contacting a part of the fourth connecting surface 24 of the reflective cup 20 and the third surface 13 of the substrate 10, and a fourth part 54 extending from the third part 53 and contacting a part of the first surface 11 of the substrate 10. A thickness of the fourth part 54 of the second electrode 50 is the same as a thickness of the third portion 43 of the first electrode 40.

Each light emitting diode chip 30 is directly connected between the first electrode 40 and the second electrode 50. In the process of manufacturing the light emitting diode package 100, there are no wires, so that the cost of the light emitting dode package 100 can be lowered. In addition, the light emitting diode package 100 can have a robust structure and a low profile. And, the second electrode 50 tightly engages with the reflective cup 20 and extends from the reflective cup 20 toward the first surface 11 of the substrate 10, whereby moisture can be effectively blocked from entering the light emitting diode package 100 to damage the light emitting diode chips 30.

Further, the light emitting diode package 100 also includes an encapsulating layer 60. The encapsulating layer 60 is made of electrically insulating materials. The encapsulating layer 60 is an electrically insulating layer between the first electrode 40 and the second electrode 50. The encapsulating layer 60 covers the light emitting diode chips 30 expect the P-type electrodes 31 and the N-type electrodes 32. A thickness of the encapsulating layer 60 is equal to a height between the second surface 12 of the substrate 10 and the electrically connecting surfaces 310 of the light emitting diode chips 30. If the light emitting diode package 100 has a single one light emitting diode chip 30, the encapsulating layer 60 may be received in a gap between a flank of the light emitting diode chip 30 and the third connecting surface 23 of the reflective cup 20. If the light emitting diode package 100 includes more than one light emitting diode chip 30, as shown in FIG. 1, the encapsulating layer 60 is received in gaps between the light emitting diode chips 30 and gaps between flanks of the light emitting diode chips 30 and the third connecting surface 23 of the reflective cup 20.

In this embodiment, the second electrode 50 directly contacts the light emitting diode chip 30, the encapsulating layer 60, the reflective cup 20 and the substrate 10.

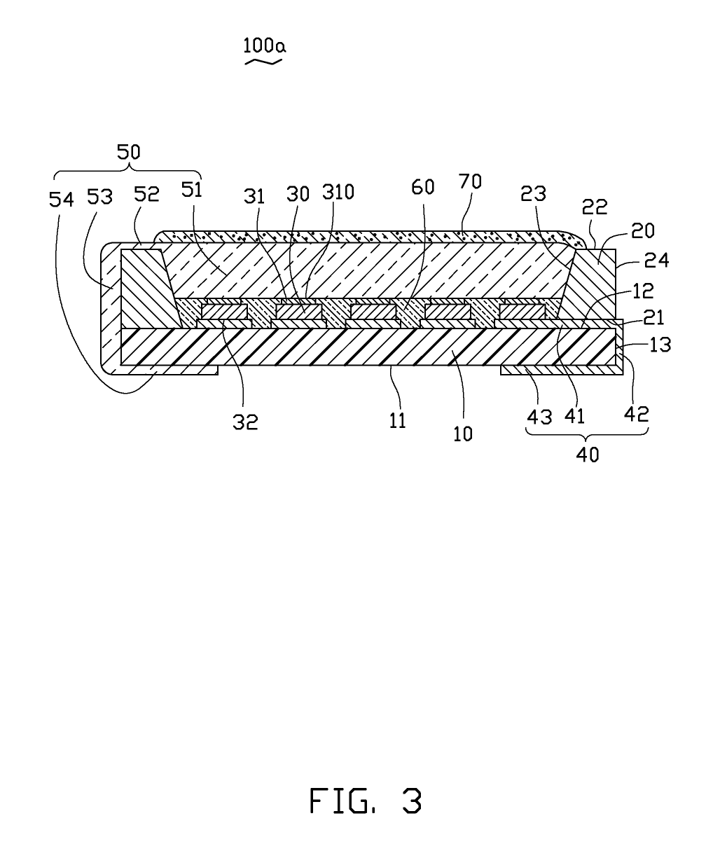

In another embodiment, a light emitting diode package 100a as shown in FIG. 3 further includes a fluorescent layer 70, which covers an upper surface of the first part 51 of the second electrode 50. The fluorescent layer 70 spans over a space above the reflective cup 20.

A light of the light emitting diode package 100 or the light emitting diode package 100a is emitted from the light emitting diode chips 30, through the second electrode 50, to an outside of the light emitting diode package 100 or the light emitting diode package 100a. In the light emitting diode package 100a, the light also radiates through the fluorescent layer 70 to activate fluorescent powders in the fluorescent layer 70 to generate a secondary light which combines with the primary light from the light emitting diode chip 30 to obtain a resultant light having a desired color, for example white. The secondary light is for example yellow light, while the primary light is for example blue light.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A light emitting diode package comprising:
a substrate having a first surface and a second surface opposite the first surface;
a reflective cup formed on the second surface of the substrate;
at least one light emitting diode chip formed on the second surface of the substrate and surrounded by the reflective cup; and
a first electrode and a second electrode electrically connected to the at least one light emitting diode chip; wherein
the at least one light emitting diode chip has a top electrode and a bottom electrode respectively at a top and a bottom thereof, the first electrode is an electrically conductive layer, the second electrode is a transparent and electrically conductive layer, the first electrode directly touches and electrically connects the bottom electrode of the at least one light emitting diode chip, the second electrode directly touches and electrically connects the top electrode of the at least one light emitting diode chip, each of the first and second electrodes having a portion extending to the first surface of the substrate.

2. The light emitting diode package of claim 1, wherein the substrate further comprises a third surface connected between the first surface and the second surface, the portion of each of the first and second electrodes extending to the first surface of the substrate being via the third surface of the substrate.

3. The light emitting diode package of claim 2, wherein the first electrode extends into the reflective cup.

4. The light emitting diode package of claim 3, wherein the first electrode comprises a first portion, a second portion and a third portion, the second portion connects the first portion and the third portion, the first portion is formed on the second surface of the substrate, the second portion extends from the first portion and is attached to the third surface of the substrate, and the third portion extends from the second portion and is attached to and beneath the first surface of the substrate.

5. The light emitting diode package of the claim 4, wherein the first portion of the first electrode has a first section sandwiched between the substrate and the reflective cup and a second section received in the reflective cup.

6. The light emitting diode package of claim 4, wherein the reflective cup comprises a first connecting surface connected to the first surface of the substrate, a second connecting surface opposite to the first connecting surface, and a third connecting surface and a fourth connecting surface connected between the first and the second connecting surface.

7. The light emitting diode package of claim 6, wherein the second electrode comprises a first part received in the reflective cup, a second part extending from the first part and covering the second connecting surface of the reflective cup, a third part extending from the second part and contacting a part of the fourth connecting surface of the reflective cup and a part of the third surface of the substrate, and a fourth part extending from the third part and contacting a part of the first surface of the substrate.

8. The light emitting diode package of claim 7, wherein a thickness of the fourth part of the second electrode is equal to a thickness of the third portion of the first electrode.

9. The light emitting diode package of claim 7, wherein the first part of the second electrode covers the at least one light emitting diode chip.

10. The light emitting diode package of claim 9, further comprising an encapsulating layer, wherein the encapsulating layer covers the at least one light emitting diode chip expect the bottom and top electrodes thereof.

11. The light emitting diode package of claim 1, further comprising a fluorescent layer, wherein the fluorescent layer spans over the reflective cup and covers the second electrode.

12. The light emitting diode package of claim 1, wherein the at least one light emitting diode chip comprises a plurality of light emitting diode chips, and each light emitting diode chip is electrically connected to the first electrode and the second electrode.

13. The light emitting diode package of claim 12, wherein the light emitting diode chips are parallel electrically connected with each other.

14. The light emitting diode package of claim 12, wherein a thickness of the light emitting diode chips is the same as each other.

15. A light emitting diode package comprising:
a substrate having a top surface and a bottom surface;
a reflective cup formed on the top surface of substrate;
at least one light emitting diode chip mounted on the top surface of the substrate and having a bottom electrode and an opposite top electrode;
a first electrode electrically connecting the bottom electrode of the at least one light emitting diode chip; and
a second electrode electrically directly connecting the top electrode of the at least one light emitting diode chip, the second electrode being made of transparent conductive materials and covering the at least one light emitting diode chip, each of the first and second electrodes having a portion extending to the bottom surface of the substrate.
